(19) United States
(12) Patent Application Publication
(10) Pub. No.: US 2011/0057185 A1
(43) Pub. Date: Mar. 10, 2011

(54) THIN FILM TRANSISTOR

(75) Inventors: Lung-Han PENG, Taipei (TW); Sung Li WANG, Taipei (TW); Hong-Wei KUO, Taipei (TW)

(73) Assignee: NATIONAL TAIWAN UNIVERSITY, Taipei (TW)

(21) Appl. No.: 12/609,337

(22) Filed: Oct. 30, 2009

(30) Foreign Application Priority Data
Sep. 9, 2009 (TW) 098130324

(51) Int. Cl. H01L 29/786

(52) U.S. Cl. 257/43; 257/E29.296

(57) ABSTRACT

A thin film transistor includes a channel layer. The channel layer has a plurality of stacked oxide layers. The oxide layers are made of at least two different oxide materials. The channel layer modulates a threshold voltage of the thin film transistor. An insulating interface layer is formed between the channel layer and an insulating dielectric layer, thereby transforming the thin film transistor from a depletion type transistor to an enhanced type transistor.

### BACKGROUND OF THE INVENTION

1. Field of the Invention

This invention relates to thin film transistors, and more particularly, to a thin film transistor that has the characteristics of an enhanced type transistor.

2. Description of Related Art

Presently, a liquid crystal display is the most widely used one of the flat panel displays. A liquid crystal display comprises two substrates, field electrodes for generating an electric field, and a liquid crystal layer sandwiched by the substrates. By applying a voltage to the field electrodes, an electric field is generated in the liquid crystal layer of the liquid crystal display. The generated electric field orientates liquid crystal molecules in the liquid crystal layer to adjust the polarization of the incident light and determine the penetration of the light. Since an oxide thin film transistor may be fabricated on a glass substrate employed by the liquid crystal display, the oxide thin film transistor can be used to fabricate the pixels of the liquid crystal display. Moreover, since the channel of an oxide thin film transistor is formed by an optically transparent material, the liquid crystal display has improved resolution and aperture ratio. Similarly, flexible electrical application is becoming one of the most popular research fields in the art. In recent years, the flat panel display is required to have a compact size. However, the flat panel display at this stage is still dissatisfactory in portability and information display. Therefore, in order to improve the portability and information display, it is important to develop a flexible display that is flexible and has a compact size. Similarly, since the oxide thin film transistor may be fabricated on a flexible plastic substrate or on an elastic material (such a substrate cannot endure a high temperature process), the oxide thin film transistor may thus be used to fabricate a flexible display (such as electro-phoretic and cholesteric liquid crystal) and flexible electric circuit.

Since oxygen vacancies are likely to be formed in the channel material employed by the oxide thin film transistor, a great amount of electrons will be distributed in the channel at room temperature, leading the thin film transistor to be with a characteristic of depletion type transistor (i.e., a depletion type thin film transistor, which has a threshold voltage less than zero volt). However, most consumer electronics products employ a thin film transistor with a characteristic of enhanced type thin film transistor (i.e., an enhanced type thin film transistor, which has a threshold voltage greater than zero volt), in order to reduce the power consumption in a standby state. Therefore, the fabrication technique of the liquid crystal display and the application field of the flexible electronics need the enhanced type thin film transistor. In the known oxide thin film transistor technique, the electric characteristics (such as carrier mobility) of the oxide thin film transistor may be adjusted by adjusting the mixing ratio of metal ions of the channel oxide layer (e.g., by adjusting x in InₓZn₁₋ₓO), to obtain the enhanced type thin film transistor characteristics. There are two methods that adjust the mixing ratio of metal ions: the first one utilizes vapor deposition or sputtering method to deposit on a substrate a mixture of indium oxide, zinc oxide and gallium oxide that are well mixed on a vapor deposition/sputtering machine and has an prepared ratio; the second one grows a plurality of pure oxide materials at different growing rate on the substrate, to generate a mixture of the oxide materials and fabricate the channel layer of an enhanced type thin film transistor. However, the ratio of components of the oxide thin film fabricated by the first method has to be prepared in advance, and cannot be adjusted during the fabrication in the machine based on the real-time demand; and the oxide thin film fabricated by the second method is hardly controlled in mixing ratio of the oxide materials, because the oxide materials are mixed directly in a vacuum chamber and have a great diversity of characteristics. Meanwhile, the thin film does not have satisfactory flatness, transparency and electric characteristics, because there are many variances during the mixing process.

Therefore, modern liquid crystal displays and flexible electronic applications need enhanced type oxide thin film transistors to be installed therein, in view of either power consumption or electric characteristics. However, the aforesaid two methods of fabricating an oxide thin film transistor of the prior art cannot provide an oxide thin film that is easily to be fabricated and simultaneously has good electric characteristics, so as not to fabricate an enhanced type thin film transistor.

In view of the fact that the known methods of fabricating a thin film transistor in the art cannot fabricate an enhanced type thin film transistor that has good electric characteristics in an easy way, how to provide a method of fabricating a channel of a thin film transistor that is easily to adjusted and has few variances during the fabrication process so as to fabricate an enhanced thin film transistor is becoming one of the most important issues in the art.

### SUMMARY OF THE INVENTION

In view of the above-mentioned problems in the prior art, the present invention provides a thin film transistor that has an adjustable threshold voltage and the characteristics of an enhanced type transistor.

According to an embodiment of the present invention, the thin film transistor includes: a substrate; a channel layer provided on the substrate and having a plurality of stacked oxide layers that are made of two different oxide materials; a plurality of metal electrodes provided on the channel layer; an insulating dielectric layer that partially covers the metal electrodes; and a gate electrode provided on the insulating dielectric layer.

According to another embodiment of the present invention, the thin film transistor includes: a substrate; a gate electrode provided on the substrate; an insulating dielectric layer that covers the gate electrode; a channel layer provided on the insulating dielectric layer and comprising a plurality of stacked oxide layers that are made of at least two different oxide materials; and a plurality of metal electrodes provided on the channel layer.

Compared to the prior art, the thin film transistor of the present invention not only provides the characteristics of an enhanced type thin film transistor, but also has its threshold voltage be adjusted according to the required electric characteristics of the thin film transistor by adjusting the thickness of the stacked oxide layers of the channel layer.

### BRIEF DESCRIPTION OF DRAWINGS

The invention can be more fully understood by reading the following detailed description of the preferred embodiments, with reference made to the accompanying drawings, wherein:

FIG. 1 is a cross sectional view of a thin film transistor according to an embodiment of the present invention;

FIG. 2 is a cross sectional view of a thin film transistor according to another embodiment of the present invention;

FIG. 3 is a schematic cross sectional view of a channel layer of a thin film transistor according to an embodiment of the present invention;

FIG. 4 is a diagram of gate-source voltage verse gate-source current (V_{GS}-I_{DS}) of a general thin film transistor in which a channel layer comprises pure indium oxide;

FIG. 5 is a diagram of gate-source voltage verse gate-source current (V_{GS}-I_{DS}) of a thin film transistor of a first embodiment according to the present invention, wherein a channel layer is formed by stacking indium oxide and gallium oxide; and

FIG. 6 is a diagram of gate-source voltage verse gate-source current (V_{GS}-I_{DS}) of a thin film transistor of a second embodiment according to the present invention, wherein a channel layer is formed by stacking indium oxide and gallium oxide and an insulating interface layer comprises gallium oxide.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

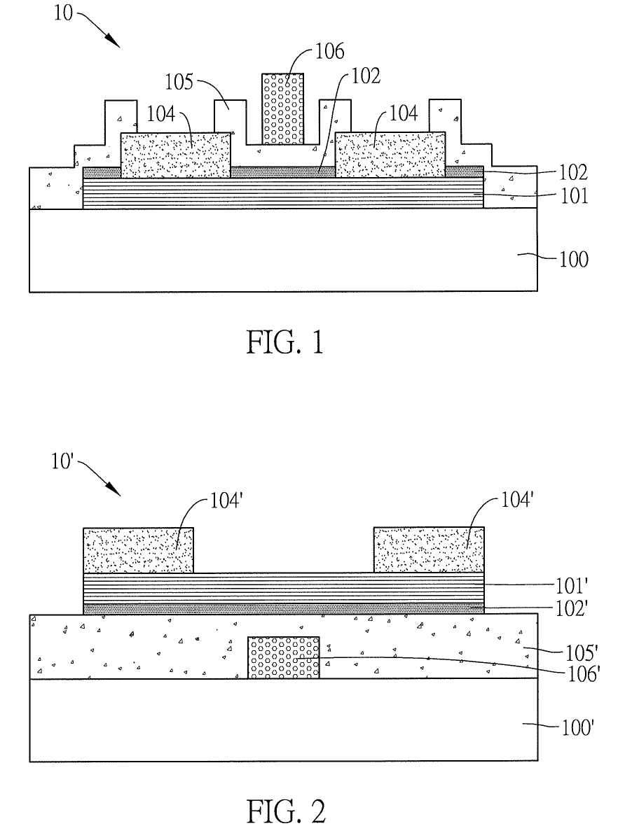

Note that since the thin film transistor of the present invention is characterized in the structure of a channel layer and an insulating interface layer of the thin film transistor and the material and method for forming the channel layer and the insulating interface layer, the process and structure of the thin film transistor related to the prior art are omitted. FIG. 1 is a cross sectional view of a thin film transistor 10 of an embodiment according to the present invention. The thin film transistor 10 comprises a substrate 100, a channel layer 101 installed on the substrate 100, a plurality of metal electrodes 104 installed on the channel layer 101, an insulating interface layer 102 installed on the channel layer 101 where is not covered by the metal electrodes 104, an insulating dielectric layer 105 that partially covers the metal electrodes 104 and covers the insulating interface layer 102, and a gate electrode 106 installed on the insulating dielectric layer 105.

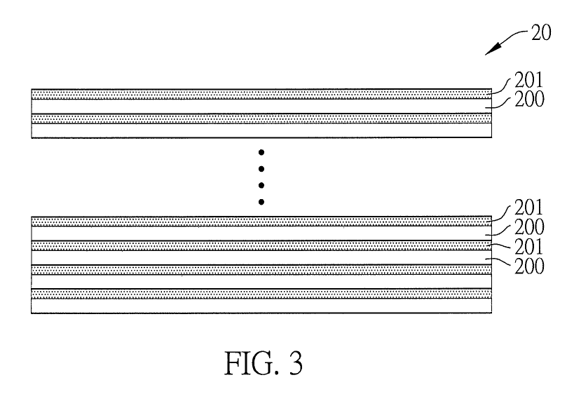

The substrate 100 is made of glass, quartz, ceramics, flexible materials, silicon-based materials or III-V group materials. The channel layer 101 is deposited on the substrate 100 by a deposition technique. The channel layer 101 comprises a plurality of non-lattice oxide layers and has a super-lattice structure, the non-lattice oxide layers comprising at least two different oxide materials and having a stack structure, which will be described in details in the following paragraphs (as shown in FIG. 3). Then, the metal electrodes 104 (which are drains and sources in the embodiment, respectively) are installed on the channel layer 101, and comprise conductive materials, such as titanium, aluminum, molybdenum, nickel and gold. Then, the insulating interface layer 102 is deposited on the channel layer 101 where are not covered by the metal electrodes 104. Then, the insulating dielectric layer 105 is deposited to cover the insulating interface layer 102 and the metal electrodes 104, except a part of the metal electrodes 104 that are used for interconnection with metal contacts (not shown) in a subsequent process. After the formation of the insulating dielectric layer 105, the gate electrode 106 is installed on the insulating dielectric layer 105 between the drains and the sources 104.

The aforesaid deposition technique comprises a vapor deposition method, chemical vapor deposition method, sputtering method, e-gun evaporation method and molecular beam epitaxy method.

The thin film transistor 10 of the present invention differs from the prior thin film transistor in that the thin film transistor 10 comprises the insulating interface layer 102 and the channel layer 101 that comprises a plurality of stacked oxide layers made of at least two different oxide materials.

FIG. 2 is a cross sectional view of a thin film transistor 10′ of another embodiment according to the present invention. The thin film transistor 10′ differs from the thin film transistor 10 shown in FIG. 1 in the locations of the gate electrode and the components of the thin film transistor. As shown in FIG. 2, in the thin film transistor 10′ a gate electrode 106′ is deposited on a substrate 100′. Then, an insulating dielectric layer 105′ is deposited to cover the gate electrode 106′ and the substrate 100′. Next, an insulating interface layer 102′ is deposited on the insulating dielectric layer 105′. Further, on the insulating interface layer 102′ a channel layer 101′ is deposited, the channel layer 101′ having a plurality of stacked oxide layers made of at least two different oxide materials. The detailed structure of the channel layer 101′ will be described in the following paragraphs. Then, on the channel layer 101′ a plurality of metal electrodes 104′ (which are drains and sources in the another embodiment, respectively) are installed. As shown in FIGS. 1 and 2, the insulating interface layers 102 and 102′ of the thin film transistors 10 and 10′ are formed by the aforesaid deposition technique between the channel layer 101 and the insulating dielectric layer 105 and between the channel layer 101′ and the insulating dielectric layer 105′, respectively. Further, the insulating interface layers 102 and 102′ comprise at least one selected from the group consisting of gallium oxide, silicon oxide, aluminum oxide, titanium oxide and the combination thereof. The insulating interface layers 102 and 102′ each has a thickness within a range of 0 to 40 angstroms. Note that in a thin film transistor of an embodiment of the present invention, the insulating interface layers 102 and 102′ are selectively installed. The existence of the insulating interface layers 102 and 102′ helps the controlling of the threshold voltage of the channel layers 101 and 101′. For example, the channel layers 101 and 101′ may have a high resistance by selecting an insulating material that has a high resistance (such as gallium oxide and silicon oxide) as the main material of the insulating interface layers 102 and 102′. Therefore, the threshold voltage of the channel layer is increased, and the depletion type thin film transistor is transformed into an enhanced type thin film transistor. Since gallium oxide and silicon oxide is thin even if its resistance is high, the interface layers 102 and 102′, when selecting gallium oxide and silicon oxide as their materials, may have a thickness within a range from 5 to 20 angstroms.

FIG. 3 is a cross sectional view of a channel layer 20 of a thin film transistor according to the present invention. The channel layer 20 is exemplarily to further describe the structures of the channel layers 101 and 101′. The channel layer 20 employs a non-lattice oxide material that has an incompact atom structure such that oxide vacancies are likely to be formed therein as a first oxide layer 200 (which is highly conductive). Additionally, another non-lattice oxide material that has a dense atom structure such that oxide vacancies are not likely to be formed therein is employed as a second oxide layer 201 (that has a high resistance). Then, the first oxide layer 200 is deposited on the second oxide layer 201. The above steps are iterated a couple of times, to form the channel layer 20, which thus has a plurality of alternatively formed first oxide layers 200 and second oxide layers 201 and has a non-lattice stacked structure.

For example, a first oxide layer 200 that is highly conductive is deposited first. Then, on the first oxide layer 200 a second oxide layer 201 that has a high resistance voltage barrier is deposited. Further, another first oxide layer 200 is deposited on the second oxide layer 201, and so on, to form the highly conductive layers and the high-resistance layers periodically and alternatively. By alternatively depositing the highly conductive layers and the high-resistance layers, a non-lattice structure is formed. The effect of controlling and adjusting the threshold voltage of the channel layer can be achieved by the alternative structure of the highly conductive layers and the high-resistance layers. How to employ the structure to control and adjust the threshold voltage of the channel layer 20 will be described in the following paragraphs.

Note that each of the first oxide layers 200 comprises at least one selected from the group consisting of indium oxide, tin oxide, zinc oxide, aluminum oxide, copper oxide and the combination thereof; and each of the second oxide layers 201 comprises at least one selected from the group consisting of gallium oxide, silicon oxide, zinc oxide and the combination thereof. Further, the first oxide layers 200, and the second oxide layer 201 as well, may comprise different materials. For example, if one of the first oxide layers 200 comprises indium oxide and one of the second oxide layers 201 deposited on the one of the first oxide layers 200 comprises gallium oxide, another of the first oxide layers 200 deposited on the one of the second oxide layers 201 may comprise tin oxide; or, if the first oxide layer 200 comprises tin oxide, the second oxide layer 201 may comprise gallium oxide; or, if the first oxide layer 200 comprises zinc oxide, the second oxide layer 201 may comprise gallium oxide; or, if the first oxide layer 200 comprises indium oxide, the second oxide layer 201 may comprise zinc oxide. In other words, the first oxide layers 200 and the second oxide layers 201 may have their materials be adjusted according to the required electrical characteristics (such as threshold voltage). That is, the channel layer 20 is formed by stacking a plurality of oxide layers made of at least two different oxide materials, one of which is highly conductive, and the other of which is of high resistance.

Further, the equivalent concentration of the oxygen vacancies of the channel layer 20 may be changed by adjusting the thickness of the first oxide layers 200 and the second oxide layers 201 in the channel layer 20. When the equivalent concentration of the oxygen vacancies of the channel layer 20 is reduced gradually, the threshold voltage required to conduct the thin film transistor is changed from a negative voltage to a positive voltage gradually, that is, the thin film transistor becoming an enhanced type thin film transistor. In the embodiment, the first oxide layer 200 has a thickness from 5 to 100 angstroms, while the second oxide layer 201 has another thickness within 0.1 to 100 angstroms.

In the embodiments described later, a total number of layers stacked to form the channel layer 20 is from 2 to 100, and the channel layer 20 has a total thickness from 100 to 1000 angstroms.

In order to distinguish the thin film transistor of the present invention, which has an adjustable threshold voltage and therefore provides the characteristics of an enhanced type thin film transistor, from the prior art, a general thin film transistor (not shown) is exemplary to further describe the aforesaid effect of the thin film transistor of the present invention, the general thin film transistor having no channel layer that comprises a plurality of stacked oxide layer made of at least two different oxide materials and no deposited insulating interface layers 102 and 102′. The general thin film transistor takes optically transparent glass, quartz or ceramics, flexible material (plastic or stainless steel), silicon-based material or III-V group material as a substrate; then, molybdenum metal having a thickness of 1,000 angstroms is used as the drain and source; silicon nitrogen having a thickness of 400 angstroms is used as an insulating dielectric layer; molybdenum metal having a thickness of 2,000 angstroms is used to form a gate electrode installed on the insulating dielectric layer; and a channel layer is formed by depositing pure indium oxide of 500 angstroms, that is the oxide materials forming the channel layer being the same oxide materials.

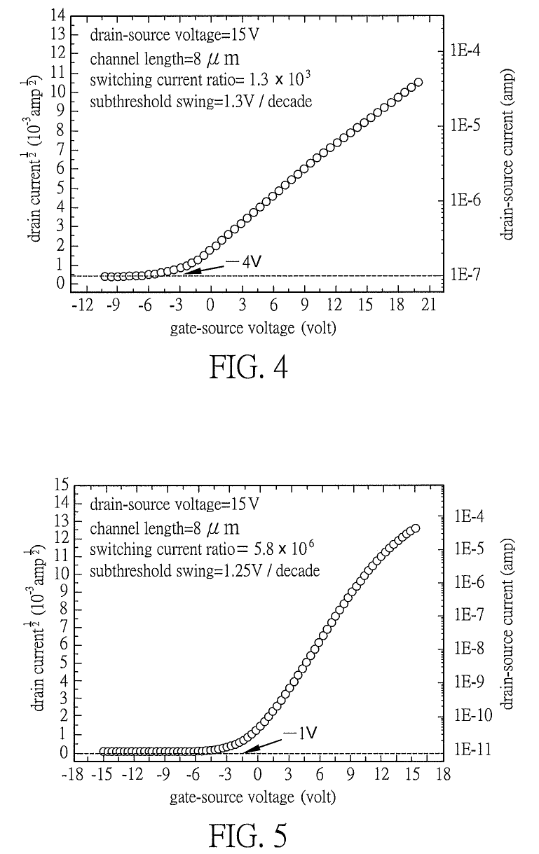

FIG. 4 is a diagram of gate-source voltage verse gate-source current (V_{GS}-I_{DS}) of the aforesaid general thin film transistor. A 15-volt drain-source (V_{DS}) is applied to the general thin film transistor. The channel in the gate direction is 8 μm long. As shown in FIG. 4, the thin film transistor has a switching current ratio (Iₒₙ/I_{off}) being about 1.3×10³, a subthreshold swing being about 1.3V/decade, and a threshold voltage equal to −4V, and is a depletion type thin film transistor.

The first embodiment according to the present invention illustrates the thin film transistor 10 shown in FIG. 1. However, in the first embodiment no insulating interface layer 102 is deposited, and the channel layer 101 has the stacked structure as shown in FIG. 3, and is formed to have an indium oxide layer/gallium oxide layer non-lattice structure by iteratively and alternatively stacking indium oxide layers (as the first oxide layer 200) and gallium oxide layer (as the second oxide layer 201), each of the indium oxide layers being 32 angstroms thick, each of the gallium oxide layers being 2.5 angstroms thick, the channel layer 101 having fifteen sets of indium oxide layer/gallium oxide layer stacked structure, that is thirty oxide layers in total, and the channel layer 101 being about 517.5 angstroms thick.

FIG. 5 is a diagram of gate-source voltage verse gate-source current (V_{GS}-I_{DS}) of the thin film transistor of the first embodiment according to the present invention. The same as the exemplary contrast of aforesaid general thin film transistor, the 15-volt drain-source (V_{DS}) is also applied to the thin film transistor, and the channel in the gate direction is also 8 μm long. As shown in FIG. 5, the thin film transistor has a switching current ratio (Iₒₙ/I_{off}) being about 5.8×10³, a subthreshold swing being about 1.25V/decade, and a threshold voltage equal to −1.0V, and is also a depletion type thin film transistor. Although the thin film transistor of the first embodiment is still a depletion type thin film transistor, the characteristics of the thin film transistor are greatly improved, as compared with those of the exemplary contrast of the general thin film transistor.

Moreover, following the first embodiment, the channel layer 101 has the stacked structure shown in FIG. 3, which is formed by iteratively and alternatively stacking indium oxide layers (or tin oxide layers, zinc oxide layers) (as the first oxide layer 200) and gallium oxide layers (as the second oxide layer 201), each of the indium oxide layers (tin oxide layers, zinc oxide layers) having a thickness within a range of 5 to 100, preferably within a range of 20 to 40 angstroms, each of the gallium oxide layers having a thickness within a range of 0.1 to 100, preferably within a range of 1 to 10 angstroms.

Moreover, following the first embodiment, the channel layer 101 has the periodic indium oxide layer/zinc oxide layer stacked structure, which is formed by iteratively and alternatively stacking indium oxide layers (as the first oxide layer 200) and zinc oxide layers (as the second oxide layer 201), each of the indium oxide layers having a thickness within a range of 0.1 to 100, preferably within a range of 1 to 40 angstroms, each of the zinc oxide layers having a thickness within a range of 0.1 to 100, preferably within a range of 1 to 40 angstroms.

Moreover, following the first embodiment, the channel layer 101 may have the periodic indium zinc oxide layer (InₓZn₁₋ₓO, 0<x<1)/gallium oxide layer stacked structure, which is formed by iteratively and alternatively stacking indium zinc oxide layers and gallium oxide layers, each of the indium zinc oxide layers having a thickness within a range of 5 to 100, preferably within a range of 20 to 40 angstroms, each of the gallium oxide layers having a thickness within a range of 0.1 to 100, preferably from 1 to 10 angstroms.

Further, following the first embodiment, the channel layer 101 may have a super-lattice structure by iteratively and alternatively stacking the first oxide layers 200 and the second oxide layers 201, each of the first oxide layers comprising at least one selected from the group consisting of indium oxide, tin oxide, zinc oxide, aluminum oxide, copper oxide and the combination thereof, each of the second oxide layers 201 comprising at least one selected from the group consisting of gallium oxide, silicon oxide, zinc oxide and the combination thereof. Further, in another embodiment according to the present invention, the layers that form the stacked structure of the channel layer (including the first oxide layers 200 and the second oxide layers 201) may comprise one selected from the group consisting of indium oxide, tin oxide, zinc oxide, aluminum oxide, copper oxide and the combination thereof. The aforesaid oxide materials have to be mixed at an appropriate ratio, and then deposited to form the channel layer that has the stacked structure. The channel layer thus has a threshold voltage controllable and adjustable based on the required electrical characteristics by adjusting the ratio of the mixed oxide materials.

For example, by mixing zinc oxide with aluminum oxide in an appropriate ratio to form the first oxide layer 200 and mixing gallium oxide with silicon oxide in another appropriate ratio to form the second oxide layer 201, a highly conductive layer that has a conductive characteristic between zinc oxide and aluminum oxide and a high resistance voltage barrier layer that has a resistive characteristic between oxide gallium and silicon oxide are generated. Accordingly, a channel layer of a thin film transistor that has a different threshold voltages is formed.

A thin film transistor of a second embodiment according to the present invention is described in the following paragraphs. The second embodiment differs from the first embodiment in that in the second embodiment the insulating interface layer 102 is installed on the channel layer 101. In other words, the second embodiment has the structure of the thin film transistor 10 shown in FIG. 1. In the second embodiment, the insulating interface layer 102 comprises gallium oxide having a thickness of 20 angstroms, and the insulating interface layer 102 comprises silicon oxide, aluminum oxide or titanium oxide. The insulating interface layer 102 may have a thickness within a range of 5 to 20 angstroms if it comprises gallium oxide or silicon oxide.

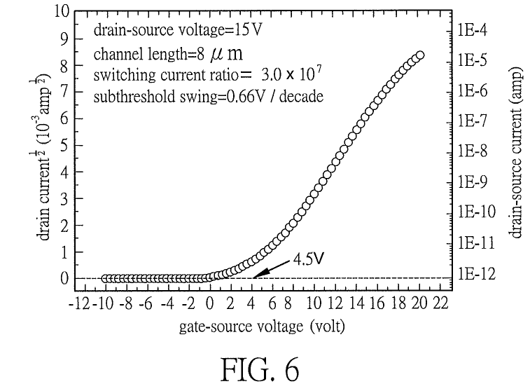

FIG. 6 is a diagram of gate-source voltage verse gate-source current (V_{GS}-I_{DS}) of the aforesaid thin film transistor of the second embodiment according to the present invention, wherein the insulating interface layer comprises gallium oxide having a thickness of 20 angstroms. A 15-volt drain-source (V_{DS}) is applied to the thin film transistor. The channel in the gate direction is 8 μm long. As shown in FIG. 6, the thin film transistor has a switching current ratio being about 3.0×10⁷, a subthreshold swing being about 0.66 V/decade, and a threshold voltage equal to 4.5 V, and thus is an enhanced type thin film transistor.

In sum, the stacked structure of the channel layer of the thin film transistor disclosed in the present invention may increase the threshold voltage and improve the electrical characteristics of the thin film transistor dramatically. Further, the electrodes (i.e., drain, source or gate electrode) of the thin film transistor of the present invention may comprise general metal materials, or common transparent electrodes, such as ITO, IZO, etc. The number of stacked layers, the thickness of each of the stacked layers, and the materials of the super-lattice structure of the channel layer may be adjusted based on the required threshold voltage, and the threshold voltage moves toward a positive voltage or toward a negative voltage depending on the number of stacked layers, the thickness of each of the stacked layers, and the materials. In addition to the channel layer, the insulating interface layer formed between the channel layer and the insulating dielectric layer may further adjust or control the threshold voltage of the thin film transistor. The insulating interface layer may comprise silicon nitrogen or insulating oxide that has a high dielectric coefficient (k), such as tantalum oxide (Ta₂O₅) and hafnium oxide (HfO₂).

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A thin film transistor, comprising:
a substrate;
a channel layer provided on the substrate and comprising a plurality of stacked oxide layers that are made of at least two different oxide materials;
a plurality of metal electrodes provided on the channel layer;
an insulating dielectric layer that partially covers the metal electrodes; and
a gate electrode provided on the insulating dielectric layer.

2. The thin film transistor of claim 1, wherein one of the at least two different oxide materials has a high conductance, and the other of the at least two different oxide materials has a high resistance.

3. The thin film transistor of claim 1, wherein the stacked oxide layers comprise 2 to 100 oxide layers, and have a thickness from 100 to 1000 angstroms.

4. The thin film transistor of claim 3, wherein the stacked oxide layers are stacked alternatively with the at least two different oxide materials.

5. The thin film transistor of claim 1 further comprising an insulating interface layer provided between the channel layer and the insulating dielectric layer and disposed beside the metal electrodes.

6. The thin film transistor of claim 5, wherein the insulating interface layer comprises at least one selected from the group consisting of gallium oxide, silicon oxide, aluminum oxide, titanium oxide and the combination thereof.

7. The thin film transistor of claim 6, wherein the insulating interface layer has a thickness less than 40 angstroms.

8. The thin film transistor of claim 1, wherein the at least two oxide materials comprise one selected from the group consisting of the combination of indium oxide and gallium oxide, the combination of tin oxide and gallium oxide, the combination of zinc oxide and gallium oxide, and the combination of indium oxide and zinc oxide.

9. The thin film transistor of claim 1, wherein one of two different oxide layers among the stacked oxide layers made of the at least two different oxide materials has a thickness from 5 to 100 angstroms, and the other of the two different oxide layers has another thickness from 0.1 angstrom to 100 angstroms.

10. The thin film transistor of claim 1, wherein the at least oxide materials comprise at least one selected from the group consisting of indium oxide, gallium oxide, tin oxide, zinc oxide, aluminum oxide and copper oxide.

11. A thin film transistor, comprising:
a substrate;
a gate electrode provided on the substrate;
an insulating dielectric layer that covers the gate electrode;
a channel layer provided on the insulating dielectric layer and comprising a plurality of stacked oxide layers that are made of at least two different oxide materials; and
a plurality of metal electrodes provided on the channel layer.

12. The thin film transistor of claim 11, wherein one of the two different oxide materials has a high conductance, and the other of the two different oxide materials has a high resistance.

13. The thin film transistor of claim 11, wherein the stacked oxide layers comprise 2 to 100 oxide layers, and have a thickness from 100 to 1000 angstroms.

14. The thin film transistor of claim 11, wherein the stacked oxide layers are stacked alternatively with the at least two different oxide materials.

15. The thin film transistor of claim 11 further comprising an insulating interface layer provided between the channel layer and the insulating dielectric layer.

16. The thin film transistor of claim 15, wherein the insulating interface layer comprises at least one selected from the group consisting of gallium oxide, silicon oxide, aluminum oxide, titanium oxide and the combination thereof.

17. The thin film transistor of claim 15, wherein the insulating interface layer has a thickness less than 40 angstroms.

18. The thin film transistor of claim 11, wherein the oxide materials comprise one selected from the group consisting of the combination of indium oxide and gallium oxide, the combination of tin oxide and gallium oxide, the combination of zinc oxide and gallium oxide, and the combination of indium oxide and zinc oxide.

19. The thin film transistor of claim 11, wherein one of two different oxide layers among the stacked oxide layers made of the at least two different oxide materials has a thickness from 5 to 100 angstroms, and the other of the two different oxide layers has another thickness from 0.1 angstrom to 100 angstroms.

20. The thin film transistor of claim 11, wherein the at least oxide materials comprise at least one selected from the group consisting of indium oxide, gallium oxide, tin oxide, zinc oxide, aluminum oxide and copper oxide.
